(19) United States
(12) Patent Application Publication
(10) Pub. No.: US 2005/0103374 A1
(43) Pub. Date: May 19, 2005

(54) Solar power collection with near infrared wideband reflector coating

(75) Inventor: Robert M. Moy, Redondo Beach, CA (US)

Correspondence Address: SHIMOKAJI I FRITZ LLP, Suite 480, 1301 Dove Street, Newport Beach, CA, 92660, US

(73) Assignee: The Boeing Company, Chicago, IL (US)

(21) Appl. No.: 10/713,489

(22) Filed: Nov. 14, 2003

(51) Int. Cl. H01L 31/00

(52) U.S. Cl. 136/246; 136/255

(57) ABSTRACT

A near infrared (NIR) wideband reflector coating designed to start reflecting solar energy wavelengths from at least 1.2 microns in a typical geosynchronous earth orbit or medium earth orbit satellite and from at least 1.3 microns in a typical low earth orbit satellite. Also, the (NIR) wideband reflector coating reflects solar energy wavelengths below 0.35 microns in all three applications. This invention works on triple junction (TJ) solar cells. The performance of at least 1.2-microns is on solar panels with near-normal incident solar angle, typical of Geosynchronous Earth Orbit (GEO) and Medium Earth Orbit (MEO) satellites. The performance of at least 1.3-microns is on solar panels with wide range of incident solar angles, a design requirement for Low Earth Orbit (LEO) satellites.

### BACKGROUND OF THE INVENTION

The present invention generally relates to a coating to improve solar power collection in space applications, more particularly, the coating cools the solar cells by reflecting wavelengths in the near infrared wideband not used by the solar cells thereby reducing the cells' solar absorptance. Cooler solar cells convert electrical power more efficiently, and thus improve solar power collection.

Present satellite designs use the highest efficiency cells available and as many solar panels as physically possible. Past attempts to increase solar power generation have included developing new solar cells with higher conversion efficiency or adding more solar panels to the satellite or a combination of both solutions. Developing new solar cells is a very costly and time-consuming route and adding more solar panels increases cost, adds weight, increases deployment risk, and adds attitude control complexity. A way to increase solar power generation without increasing the solar cell's conversion efficiency or having to add more solar panels is needed.

Satellites, such as most low earth orbit (LEO) satellites, and space vehicles that have stowed volume and launch weight constraints cannot simply add additional solar panels. These satellites and space vehicles will have to limit mission operations or redesign all the payloads to meet the power limitation.

As can be seen, there is a need for increasing power generation in a satellite without developing new higher efficiency solar cells. Furthermore, there is a need to improve power generation without adding more solar panels.

### SUMMARY OF THE INVENTION

The present invention provides a method of decreasing a solar cell's operating temperature for higher conversion efficiency by reducing the cell's solar absorptance of a solar panel, the solar panel containing triple junction solar cells, the method comprising the steps of: providing a near infrared (NIR) wideband reflector coating before the triple-junction solar cells, the coating being 8 to 12 microns thick; passing desired wavelengths of solar energy through the coating to the triple-junction solar cells of 0.35 to at least 1.15 microns; and reflecting the unused wavelengths of 1.2 to 2.5 microns and the undesired below 0.35 microns wavelengths of solar energy from the coating and away from the triple junction solar cells to reduce an operation temperature at least 20 degrees C.

In another aspect of the present invention, a method of improving solar power collection in solar panels with triple-junction solar cells of a satellite includes the steps of providing a near infrared (NIR) wideband reflector coating before the triple-junction cell solar cells; allowing solar energy wavelengths of at least 0.35 microns through the coating to contact the triple-junction solar cells; and reflecting solar energy wavelengths below 0.35 from the coating and away from the triple-junction solar cells.

In another aspect of the present invention, a method of decreasing a solar cell's operating temperature for higher conversion efficiency comprising the steps of: providing a coating on an coverglass of a solar panel, the coating being about 8 to 12 microns thick; placing at least one triple-junction solar cell under the coverglass, the triple-junction solar cell is in a three-axis or spinning solar panel; allowing solar energy wavelengths of at least 0.35 microns pass through the coating; and reflecting wavelengths below 0.35 and above at least 1.15 microns of solar energy from the coating to reduce an operation temperature at least 20 degrees C.

In still another aspect of the present invention, a method of reflecting unused solar energy by using a NIR wideband reflector coating to reduce overall solar energy absorptance and increasing power collection of a triple-junction solar cell on a satellite, the method comprising the steps of: providing the coating; placing at least one triple-junction solar cell under the coating; allowing solar energy wavelengths of at least 0.35 microns to pass through the coating; and reflecting wavelengths below 0.35 microns and above at least 1.15 microns of solar energy from the coating to reduce an operation temperature at least 20 degrees C.

In still another aspect of the present invention, a NIR wideband reflector coating for reflecting unused solar energy is provided to reduce overall solar energy absorptance and increase power collection of a triple-junction solar cell on a satellite, the coating incuding: first elements to allow solar energy wavelengths of at least 0.35 microns to pass through the coating, the triple-junction solar cell under the coating; and second elements to reflect solar energy wavelengths below 0.35 microns and above at least 1.15 microns, the coating to reduce an operation temperature at least 20 degrees C.

These and other features, aspects and advantages of the present invention will become better understood with reference to the following drawings, description and claims.

### BRIEF DESCRIPTION OF THE DRAWINGS

FIG. 1 is a graph of a bottom germanium (Ge) subcell spectral response and current collection under air mass zero (AM0) versus wavelength, of one embodiment of the present invention.

FIG. 2 is a graph of transmission and cell quantum efficiency (Q.E.) versus wavelength with top subcell, middle subcell, bottom subcell and NIR wideband reflector coating design curve, of one embodiment of the present invention.

FIG. 3 is a graph of transmission and absorptance over wavelength with absorptance, transmission and visible transmission curves, of one embodiment of the present invention.

FIG. 4 is a graph of transmission over wavelength for a typical product with actual and predicted performance curves, of one embodiment of the present invention.

FIG. 5 is a diagram showing the triple-junction (TJ) solar cell inside the solar panel and the coating on the coverglass, of one embodiment of the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

Broadly, the present invention provides a method of improving solar power collection with a NIR wideband reflector coating on a solar panel used in satellites. By reflecting unused wavelengths of solar energy the present invention lowers the operating temperature of the solar panel. At a lower operating temperature the electrical conversation efficiency increases therefore producing more power from the solar energy received. The present invention does this by reflecting a large portion of the NIR solar spectrum in addition to reflecting ultraviolet (UV) solar energy that is unused by a triple junction (TJ) cell for power generation but only heats up the TJ cell and reduces performance. Higher performance is gained from the solar panel without redesigning the solar panel or solar cells and without adding more solar panels or solar cells. The present invention adds a coating that will increase performance of a TJ solar cell within a solar panel.

There are three approaches to increase satellite power generation without solar panel area increase or solar cell technology improvement. They are as follows: (1) decrease the solar cell operating temperature for higher electrical conversion efficiency, (2) increase solar cell packing density for more solar energy conversion capability per unit area, and (3) increase solar cell coverglass thickness, for example, 20 mils, to reduce performance degradation due to the space radiation environment. The latter two approaches, higher cell density and thicker coverglass, have weight impact.

The first approach, to cool the solar cells for higher electrical conversion efficiency, may have negligible weight impact. According to one embodiment of the present invention, this approach uses a NIR wideband reflector coating. The NIR wideband reflector coating is about 8 to 12 microns thick, (based on the coating design); and it is applied to the solar cell coverglass. Twenty degrees C. reduction for Geosynchronous Earth Orbit/Medium Earth Orbit (GEO/MEO) satellites and 26 degrees C. reduction for LEO satellites is possible resulting in a 1.1 and 1.4% in absolute electrical conversion efficiency gain, respectively. The more than 1% gain in electrical conversion efficiency is significant since advanced solar cell improvement of similar performance gain requires years of costly development and qualification. This efficiency gain translates to 4% more power for GEO/MEO satellites and 8% more power for LEO satellites.

Present three-axis solar panel operating temperature can be over 40 degrees C. for GEO/MEO satellites and over 70 degrees C. for LEO satellites. This high operating temperature decreases the solar cell electrical conversion performance. The state-of-the-art TJ solar cell has a temperature conversion efficiency coefficient of −0.055% per degree C. It is understood that a solar panel may contain one or more solar cells. This implies that there is over a 1% absolute solar cell electrical conversion gain if the solar panel is 20 degrees C. cooler.

The NIR wideband reflector coating reflects the unused solar energy and reduces the overall solar absorptance of the solar cell. The expected solar absorptance reduction is 0.15 with minimum impact to solar energy conversion efficiency. A perfect black body has a solar absorptane of 1.0. The present invention can reduce the black body solar absorptance by 0.15 or to a final value of 0.85. The corresponding temperature reduction is approximately 20 degrees C. for GEO/MEO satellites and approximately 26 degrees C. for LEO satellites. The cooler solar cells can gain 1.1% of absolute efficiency or 4% more power for GEO/MEO satellites and 1.4% of absolute efficiency or 8% more power for LEO satellites.

The NIR wideband reflector coating rejects unneeded solar energy to reduce the cell's solar absorptance. Coatings that reject some portions of the solar spectrum have been applied to silicon cells, single-junction gallium arsenide (GaAs) cells, and dual-junction GaAs cells. These coatings are simple optical band-pass filters with some solar absorptance reduction. These coatings typically reflect the Ultra-violet (UV) and the red portion of the visible solar spectrum not used by the silicon and GaAs single-junction cells. The coating for dual-junction cells, called narrowband infrared (IR) reflector, rejects a small portion of the NIR. These simple coatings reduce only a small amount of the solar cell's solar absorptance; and they do not work with the latest state-of-the-art TJ solar cells.

The NIR wideband reflector coating, in the present invention, is designed and developed to reflect a large portion of the unused NIR solar spectrum in addition to UV. The TJ cell does not use solar energy below 0.35 micron; this is where the UV range exists. In fact, UV radiation degrades the adhesive, causing it to darken, which reduces solar energy transmission. Typical solar cell cover glass is treated (either with a coating called Ultra Violet Reflector, UVR, or with cerium doped in the glass) to limit UV radiation transmission, thereby protecting the adhesive. Therefore, reflecting solar energy below 0.35 microns is not new. What is new is solar energy reflection above 1.15 microns (NIR) for the TJ solar cell. The reason this is new is that the TJ solar cell converts solar energy from 0.35 to 1.8 microns, and the NIR wideband reflector coating approach is to reflect solar energy from 1.2 microns without impacting solar energy conversion capability.

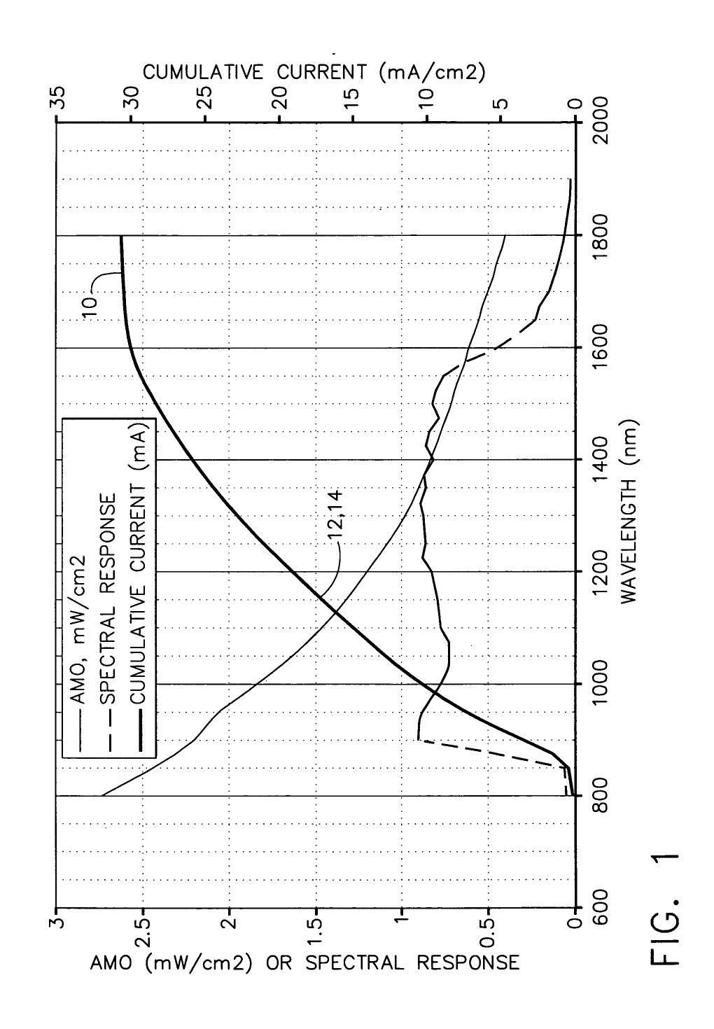

The solar cell design goal is to convert all available solar energy across the solar spectrum into electricity. The latest TJ gallium indium phosphorus/gallium arsenic/germanium (GalnP/GaAs/Ge) cell converts photons into electricity from 0.35 to 1.8 microns in three subcells. The subcells are in series, thus the least current generating subcell limits the cell current or the total cell performance. The bottom Ge subcell produces more electrical current than needed. Spectrolab has computed the required or minimum TJ absorptance spectral bandwidth. FIG. 1 shows the Ge bottom subcell's cumulative current 10 as a function of wavelengths. The subcell current density that is required for the latest TJ cell is 17 mA per square cm. As shown in FIG. 1, the bottom Ge subcell accumulates the required 17 mA per square cm 12 at 1.15 microns 14. This implies that solar energy beyond 1.15 microns is not needed by the TJ solar cell. If solar energy above 1.15 microns is reflected, the solar cell solar absorptance is reduced with no reduction in solar cell performance.

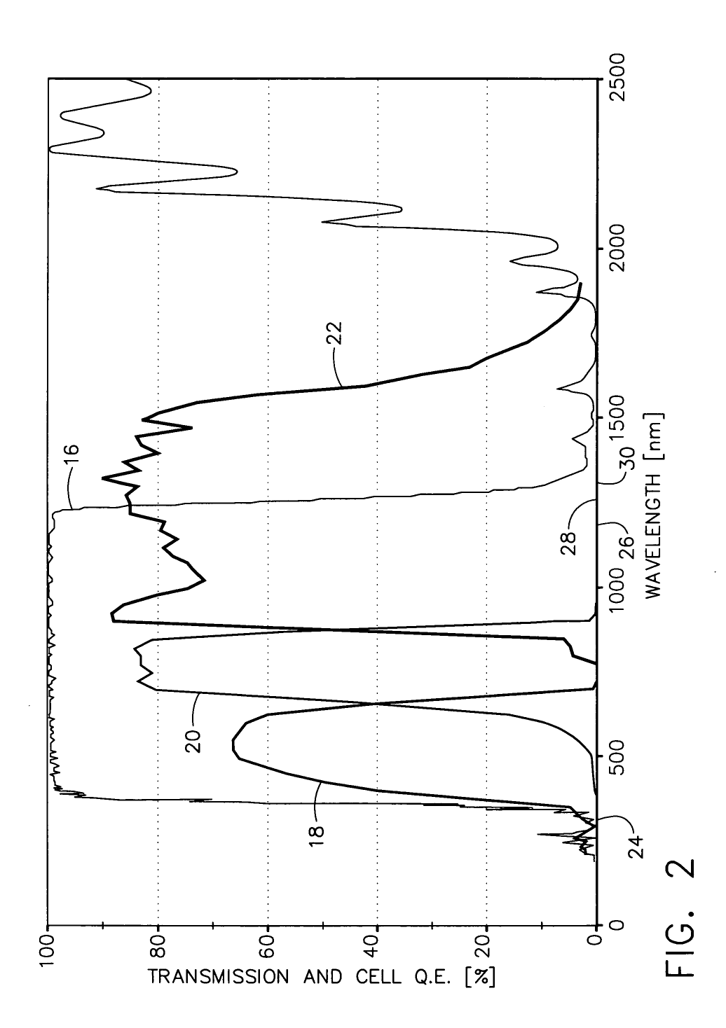

FIG. 2 illustrates the coating concept. FIG. 2 shows the three TJ subcells' quantum efficiency (Q.E.) and the NIR wideband reflector coating design 16. A top subcell 18, a middle subcell 20, and a bottom subcell 22 curve is shown. Nearly 20% of the solar energy is in the region below 0.35 microns 24 and in the region above 1.15 microns 26. Reflecting this energy will reduce the cell's solar absorptance resulting in lower operating cell temperature.

The present NIR wideband reflector coating is designed to start reflecting solar energy wavelengths at 1.2 microns 28 and longer for a typical GEO or MEO satellite and at 1.3 microns 30 and longer for a typical LEO satellite, as shown in FIG. 2. The 1.2 micron starting point is for solar panels with near-normal incident solar angle, typical for GEO satellites. The 1.3 micron starting point is for solar panels with wide range of incident solar angles, a design requirement for LEO satellites.

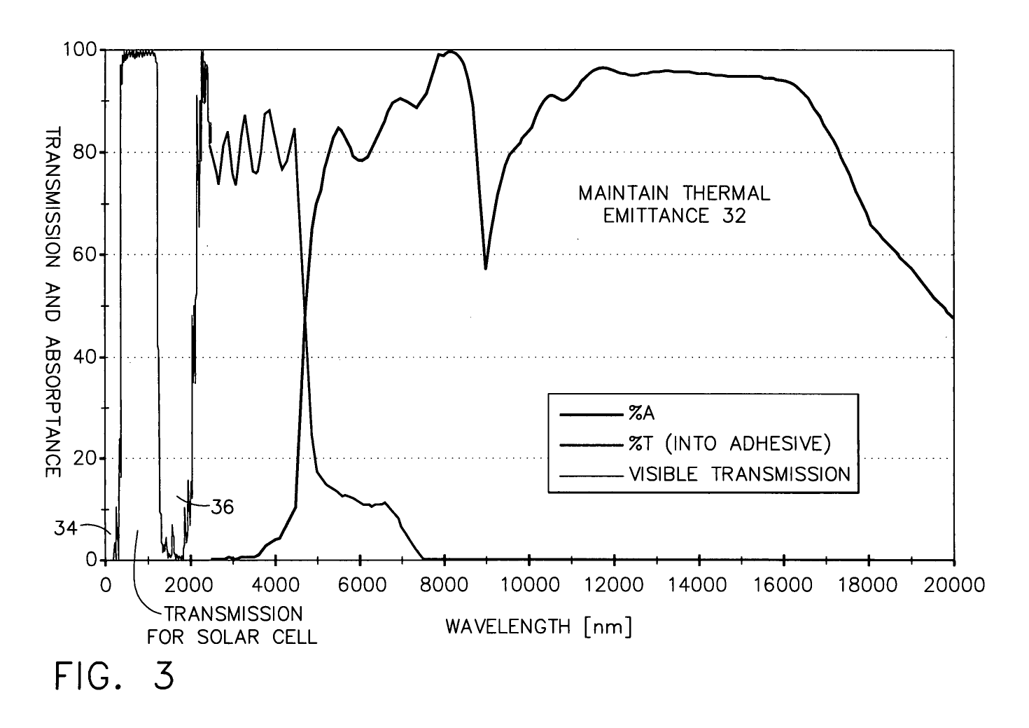

FIG. 3 shows the coating performance requirements. This NIR wideband reflector coating has been developed and demonstrated to reflect solar energy below 0.35 microns and above 1.2 and 1.3 microns while maintaining similar solar cell transmission band for the cell, the transmission band is from 0.35 to 1.2 or 1.3 microns, and thermal emittance 32, above about 9.0 microns remains the same as with the present typical solar cell coverglass. The UV rejection 34 area, at least below 0.35 microns, is shown in FIG. 3 where removing the UV solar energy protects the adhesive from degradation and darkening, which would reduce solar transmission. The NIR rejection 36 area, above 1.2 and 1.3 microns, is shown in FIG. 3, this area reduces the unused solar energy reducing the operating temperature. The present NIR wideband reflector coating design gave a 0.14 of absolute solar cell solar absorptance reduction.

A coating has been demonstrated that can reflect solar energy below 0.35 and above 1.2 microns resulting in over 0.14 of solar absorptance reduction with minimum impact to solar cell in-band transmission. The predicted transmission loss between 0.4 and 1.2 microns averaged about 2% and is similar to typical Anti-Reflection (AR) coated cerium-doped solar cell coverglass. Measurement of these initial runs shows similar solar absorptance reduction and transmission performance to that predicted.

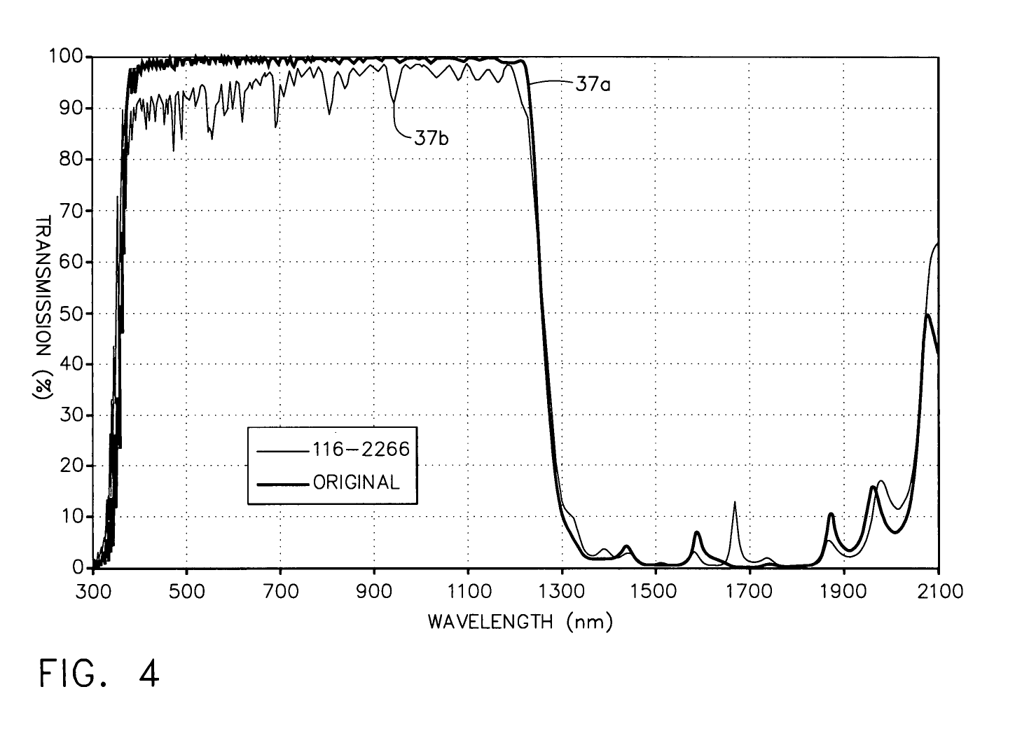

FIG. 4 shows a typical wideband reflector coating measured performance 37a on an actual coated part compared to adjusted performance 37b (index-matched to glass and normalized for coverglass to cell interaction).

Spectrolab's Improved Triple-Junction (ITJ) solar cell efficiency, as of 2002, is 26.5% at 28 degrees C. and under standard Air Mass Zero (AMO) conditions. AMO refers to a solar constant or air mass zero defining the solar radiation intensity in space. The next improvement, Ultra Triple-Junction (UTJ) cells, up to 27.5%, as of mid 2003. The 1% of absolute increase took significant efforts, cost, and time to develop and to qualify.

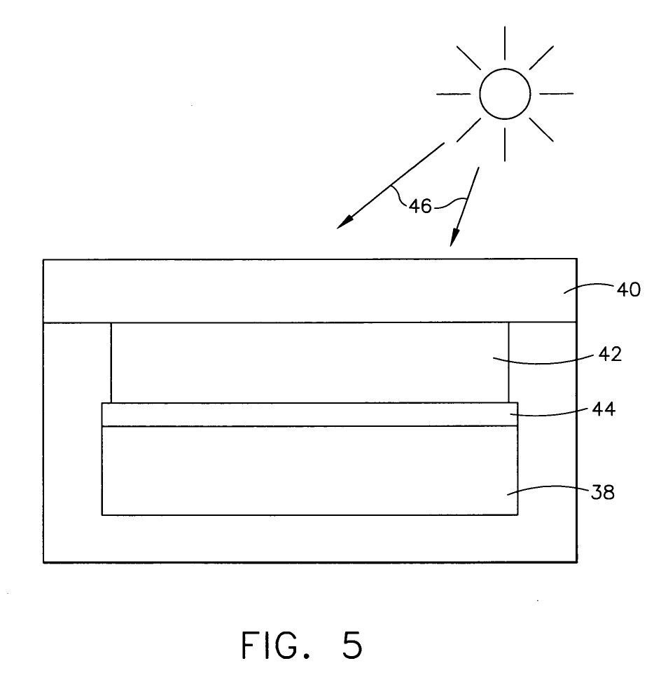

FIG. 5 shows the TJ solar cell 38 inside the solar panel 40. Also shown is the coating 42 on the coverglass 44. FIG. 7 shows solar energy 46 entering the solar panel. The NIR wideband reflector offers the same or more improvement with the UTJ solar cells. This NIR wideband reflector coating is applicable to all triple-junction cells. That is, if the 26.5% ITJ cell is used and the operating temperature is 44 degrees C. (typical GEO/MEO satellites), the operating conversion efficiency is decreased to 25.6%. If the NIR wideband reflector is used, the operating temperature drops 20 degrees C. and the operating conversion efficiency is increased to 26.7%. A gain of 1.1% absolute efficiency is achieved. If the 27.5% UTJ cell is used, the operating efficiency will be only 26.6% at the typical operating temperature of GEO/MEO satellites. The NIR wideband reflector coating will decrease the solar cell operating temperature by 20 degrees C. and increase the UTJ cell's electrical conversion efficiency to 27.7%.

The improvement is greater with LEO satellites. LEO satellites typically have solar panel operating temperature as high as 70 degrees C. The NIR wideband reflector coating gives a 26 degrees C. reduction resulting in a 1.4% absolute gain in electrical conversion. This 1.4% gain in absolute electrical conversion efficiency applies to the 26.5% ITJ cells and 27.5% UTJ cells. Note that the 1.1% and 1.4% of absolute gain in electrical conversion have negligible weight impact. Table 1 summarizes the solar cell performance with and without the NIR wideband reflector coating. Table 1 shows NIR Wideband Reflector Coating having a 20° C. reduction and 1.1% efficiency gain for GEO satellites and 26° C. reduction and 1.4% efficiency gain for LEO satellites.

TABLE 1

| | | ITJ | |
|---|---|---|---|
| | | Cells | UTJ Cells |
| Standard | Efficiency @ | 26.5% | 27.5% |
| Conditions | 28° C. AMO | | |
| GEO | Efficiency @ | 25.6% | 26.6% |
| Conditions | 44° C. GEO | | |
| without NIR | | | |
| WB Coating | | | |
| GEO | Efficiency @ | 26.7% | 27.7% |
| Conditions | 24° C. GEO | | |
| with NIR WB | | | |
| Coating | | | |
| LEO | Efficiency @ | 24.2% | 25.2% |
| Conditions | 70° C. LEO | | |
| without NIR | | | |
| WB Coating | | | |
| LEO | Efficiency @ | 25.6% | 26.6% |
| Conditions | 44° C. LEO | | |
| with NIR WB | | | |
| Coating | | | |

The NIR wideband coating will have to be modified for future Four and Five-Junction (4J and 5J) cells since the most likely 4J and 5J-cell design will use all available solar energy between 0.35 and 1.8 microns. However, there is still about 4% below 0.35 microns and about 6% above 1.8 microns of solar energy. Thus, there is still a potential of absolute solar cell solar absorptance reduction. The cell operating temperature reduction and the cell electrical conversion efficiency gain with the modified NIR wideband coating for 4J and 5J cells would be less than with the NIR wideband coating for TJ cells. Therefore, the same approach to reflect NIR solar energy not used by the solar cell will also work for future four and five-junction solar cells.

It should be understood, of course, that the foregoing relates to preferred embodiments of the invention and that modifications may be made without departing from the spirit and scope of the invention as set forth in the following claims.

1. A method of reducing solar absorptance of a solar panel, the solar panel containing triple junction solar cells, the method comprising the steps of:
providing a coating to be adapted to be disposed about the triple-junction solar cells;
passing desired wavelengths of solar energy through the coating to the triple-junction solar cells;
reflecting undesired wavelengths of solar energy from the coating and away from the triple junction solar cells; and
reflecting unused wavelengths of solar energy from the coating and away from the triple junction solar cells.

2. The method of claim 1 wherein the desired wavelengths of solar energy is a solar cell transmission band from 0.35 microns to 1.2 microns for near solar incident angles typical of GEO and MEO applications.

3. The method of claim 1 wherein the desired wavelengths of solar energy is a solar cell transmission band from 0.35 microns to 1.3 microns for solar incident angles typical of LEO applications.

4. The method of claim 1 wherein the undesired wavelengths of solar energy is reflected below 0.35 microns.

5. The method of claim 1 wherein the unused wavelengths of solar energy is reflected above 1.2 microns.

6. The method of claim 1 wherein the solar panel has an electrical conversion gain through lower operating temperature in a spacecraft operating in space.

7. The method in claim 1 wherein an operation temperature is reduced at least 20 degrees C. for typical of GEO and MEO applications.

8. The method in claim 1 wherein an operation temperature is reduced at least 26 degrees C. for typical of LEO applications.

9. A method of improving solar power collection in solar panels with triple-junction solar cells of a satellite comprising the steps of;
providing a near infrared (NIR) wideband reflector coating before the triple-junction cell solar cells;
allowing solar energy wavelengths of at least 0.35 microns through the coating to contact the triple-junction solar cells; and
reflecting solar energy wavelengths below 0.35 microns and above at least 1.2 microns from the coating and away from the triple-junction solar cells.

10. The method of claim 9 wherein solar energy wavelengths of at least 0.35 microns to 1.2 microns are allowed through the coating for near solar incident angles typical of GEO and MEO applications.

11. The method of claim 9 wherein solar energy wavelengths of at least 0.35 microns to 1.3 microns are allowed through the coating for solar incident angles typical of LEO applications.

12. The method of claim 9 wherein solar energy wavelengths below 0.35 microns and above 1.2 microns are reflected from the coating on solar panels with near-normal incident solar angles typical of GEO and MEO applications.

13. The method of claim 12 wherein solar energy wavelengths below 0.35 microns is an ultraviolet (UV) rejection area to protect an adhesive from degrading.

14. The method of claim 9 wherein solar energy wavelengths below 0.35 microns and above 1.3 microns are reflected from the coating on solar panels with a wide range of incident solar angels typical of LEO applications.

15. The method of claims 13 and 14 wherein solar energy wavelengths below 0.35 microns is an ultraviolet (UV) rejection area to protect an adhesive from degrading.

16. A method of decreasing a solar cell's operating temperature for higher conversion efficiency comprising the steps of:
providing a coating on an coverglass of a solar panel, the coating being about 8 to 12 microns thick;
placing at least one triple-junction solar cell under the coverglass, the triple-junction solar cell is in a three panel axis or spinning solar panel;
allowing solar energy wavelengths of at least 0.35 micron and through above 1.2 or 1.3 microns pass through the coating; and
reflecting wavelengths below 0.35 micron and above 1.2 or 1.3 microns of solar energy from the coating to reduce an operation temperature at least 20 degrees C.

17. The method of claim 16 wherein the coating has a minimum impact on the solar energy conversion efficiency.

18. The method of claim 16 wherein a thermal emittance is maintained.

19. The method of claim 16 wherein there is at least 4% more power on a Geosynchronous Earth Orbit satellite.

20. The method of claim 16 wherein there is at least 4% more power on a Medium Earth Orbit satellite.

21. The method of claim 16 wherein there is at least 8% more power on a Low Earth Orbit satellite.

22. A method of reflecting unused solar energy by using a NIR wideband reflector coating to reduce overall solar energy absorptance and the cell's operating temperature resulting in an increase in power collection of a triple-junction solar cell on a satellite, the method comprising the steps of:
providing the coating;
placing at least one triple-junction solar cell under the coating;
allowing solar energy wavelengths of at least 0.35 micron and through 1.2 or 1.3 microns to pass through the coating; and
reflecting wavelengths below 0.35 micron and above 1.2 or 1.3 microns of solar energy from the coating to reduce an operation temperature at least 20 degrees C.

23. The method of claim 22 wherein overall solar absorption is reduced up to 0.15.

24. The method of claim 22 wherein the TJ solar cell has a temperature conversion efficiency coefficient of −0.055% per degree C.

25. The method of claim 22 wherein the coating is about 8 to 12 microns thick.

26. The method of claim 22 wherein there is at least a 1% of absolute solar cell electrical conversion efficiency gain if the solar panel is about 20 degrees C. cooler and the coating is on a solar panel in a Geosynchronous Earth Orbit satellite

27. The method of claim 22 wherein there is at least a 1% of absolute solar cell electrical conversion efficiency gain if the solar panel is about 20 degrees C. cooler and the coating is on a solar panel in a Medium Earth Orbit satellite.

28. The method of claim 22 wherein there is at least a 1.4% of absolute solar cell electrical conversion efficiency gain if the solar panel is about 26 degrees C. cooler and the coating is on a solar panel in a Low Earth Orbit satellite.

29. The method of claim 22 wherein the triple-junction solar cell has a subcell, the subcell has a current density of 17 mA per square cm.

30. A near infrared (NIR) wideband reflector coating for reflecting unused and undesired solar energy to reduce overall solar energy absorptance and increasing power collection of a triple-junction solar cell on a satellite, the coating comprising:
first elements to allow solar energy wavelengths of at least 0.35 micron through 1.2 or 1.3 microns to pass through the coating, to the triple-junction solar cell under the coating; and
second elements to reflect solar energy wavelengths below 0.35 micron and above 1.2 or 1.3 microns from the coating to reduce an operation temperature at least 20 degrees C.

31. The coating of claim 30 wherein overall solar absorption is reduced up to 0.15.

32. The coating of claim 30 wherein the TJ solar cell has a temperature conversion efficiency coefficient of −0.055% per degree C.

33. The coating of claim 30 wherein the coating is about 8 to 12 microns thick.

34. The coating of claim 30 wherein there is at least a 1% of absolute solar cell electrical conversion efficiency gain if the solar panel is about 20 degrees C. cooler and the coating is on a Geosynchronous Earth Orbit satellite

35. The coating of claim 30 wherein there is at least a 1% of absolute solar cell electrical conversion efficiency gain if the solar panel is about 20 degrees C. cooler and the coating is on a Medium Earth Orbit satellite.

36. The coating of claim 30 wherein there is at least a 1.4% of absolute solar cell electrical conversion efficiency gain if the solar panel is about 26 degrees C. cooler and the coating is on a Low Earth Orbit satellite.

37. The coating of claim 30 wherein the triple-junction solar cell has a subcell, the subcell has a current density of 17 mA per square cm.

38. The coating of claim 30 wherein the first and second elements are the same compound.
